(19) United States
(12) Patent Application Publication
(10) Pub. No.: US 2025/0362582 A1
(43) Pub. Date: Nov. 27, 2025

(54) OPTICAL ELEMENT HAVING A POLISHING LAYER, LITHOGRAPHY APPARATUS COMPRISING THE OPTICAL ELEMENT, AND METHOD FOR PRODUCING THE OPTICAL ELEMENT

(71) Applicant: Carl Zeiss SMT GmbH, Oberkochen (DE)

(72) Inventor: Eric EVA, Aalen (DE)

(21) Appl. No.: 19/293,478

(22) Filed: Aug. 7, 2025

Related U.S. Application Data
(63) Continuation of application No. PCT/EP2024/051650, filed on Jan. 24, 2024.

(30) Foreign Application Priority Data
Feb. 7, 2023 (DE) 10 2023 200 970.6

(51) Int. Cl. G03F 1/24; G03F 1/38; G03F 7/00

(52) U.S. Cl. CPC G03F 1/24; G03F 1/38; G03F 7/70316

(57) ABSTRACT

An optical element (100, 200, 300, 400, 500, 600, 700), includes: a substrate structure (102, 202, 302, 402, 502, 602, 702) containing at least one primary layer (110, 210, 310, 410, 510, 610, 710) containing SiO₂, with a lateral face (104, 204, 304, 404, 504, 604, 704) of the substrate structure (102, 202, 302, 402, 502, 602, 702) having a convex or concave FIG. 112, 212, 312, 412, 512, 612, 712), and a polishing layer (114, 214, 314, 414, 514, 614, 714) up to 500 μm-thick, which contains TiO₂·SiO₂ and is formed along the FIG. 112, 212, 312, 412, 512, 612, 712).

### CROSS REFERENCE TO RELATED APPLICATIONS

This is a Continuation of International Application PCT/EP2024/051650, which has an international filing date of Jan. 24, 2024, and which claims the priority of German Patent Application 10 2023 200 970.6, filed Feb. 7, 2023. The disclosures of both applications are incorporated in their respective entireties into the present Continuation by reference.

### FIELD OF THE INVENTION

The present invention relates to an optical element, to a lithography apparatus having such an optical element and to a method for producing such an optical element.

### BACKGROUND

Microlithography is used for production of microstructured component parts, for example integrated circuits. The microlithography process is performed using a lithography apparatus that comprises an illumination system and a projection system. The image of a mask (reticle) located in an object plane and illuminated using the illumination system is projected by the projection system onto a substrate, for example a silicon wafer, which is coated with a light-sensitive layer (photoresist) and is arranged in the image plane of the projection system, in order to transfer the mask structure to the light-sensitive coating of the substrate.

Driven by the desire for ever smaller structures in the production of integrated circuits, Extreme ultraviolet (EUV) lithography apparatuses which use light at a wavelength in the range of 0.1 nm to 30 nm, in particular 13.5 nm, are currently being developed. Since most materials absorb light at this wavelength, such EUV lithography apparatuses require the use of reflective optics units, i.e. mirrors, instead of refractive optics units, i.e. lens elements, as used previously.

A particular challenge here is the production of a mirror geometry, called the figure, with the required low roughness in a specific frequency range.

EP 3 274 311 B1 discloses deposition of a silica glass by sol-gel methods, flame hydrolysis and soot pressing.

This challenge exists for the different substrate materials, albeit with different mechanisms that lead to unwanted roughness in the specific frequency range.

One substrate material is titanium-doped quartz glass or TiO2-SiO2. This is sold, for example, by Corning Inc. under the “ULE” name for “Ultra-Low Expansion”. Blanks made of this material are formed in layers. A titanium ratio in the material varies with each layer, such that a titanium content or a proportion of TiO₂ alternately increases and decreases in a thickness direction. In a standard production process for EUV mirrors, the figure is ground and polished in or on a lateral face of a blank or a pane of titanium-doped quartz glass. Because the fluctuating titanium content is accompanied by fluctuating hardness, stratification streaks, called striae, are formed. In the worst case, these can lead to imaging fluctuations and should therefore be avoided.

A further substrate material is glass ceramic, for example of the Li₂O—Al₂O₃—SiO₂ type. This material is for example distributed by Schott AG under the “Zerodur” name or by Ohara GmbH under the “Clearceram” name. There can be crystallite formation here during a machining step, forming small regions with spatially crystalline arrangement form in the amorphous chain structure. Because the crystallites are harder than the surrounding amorphous region, they form spot shape defects in the figure. In the worst case, they can lead to imaging fluctuations and should therefore be avoided.

WO 2016/154 190 discloses a glass composition for use in EUV lithography, wherein the glass composition comprises: a first silicon-titanium-glass section and a second doped silicon-titanium-glass section which is mechanically connected to a surface of the first silicon-titanium-glass section, wherein the second doped silicon-titanium-glass section has a thickness greater than 0.1 inch. The thickness is thus greater than 1270 μm. This figure is incapable of compensating for the roughness of a formed figure because the figure has to be formed again in a complex manner.

US 2018/0 339 933 A1 discloses a glass ceramic for production of precision components.

### SUMMARY

Against this background, it is an object of the present invention to provide an improved optical element and in particular a method for producing an optical element.

Accordingly, an optical element is proposed. This comprises: a substrate structure containing at least one primary layer containing glass or silicon dioxide or SiO₂, wherein a lateral face of the substrate structure has a convex or concave figure, and an up to 500 μm-thick polished layer containing titanium-doped quartz glass or TiO₂—SiO₂, formed along the figure.

A substrate structure may be regarded as a support structure which is designed to maintain the shape of the figure with an accuracy required for an EUV application. The substrate structure preferably has a low coefficient of thermal expansion CTE in order to maintain the shape of the figure under operating conditions.

The substrate structure may contain one or more layers. It contains at least one layer referred to here as the primary layer, which in particular fulfills the support function for the figure.

The substrate structure has a lateral face in or on which the figure is formed. The substrate structure typically takes the form of a pane, where expansion of the substrate structure in the lateral face is typically greater than expansion in a direction perpendicular to the lateral face.

The figure is generally concave. This applies to EUV applications in particular. Therefore, a concave figure is preferred. However, the invention is also applicable to convex figures.

The above proposal envisages formation of a polished layer along the figure. The proposal is thus that the substrate structure first be endowed with the figure and then the figure be lined with the polished layer. It is possible here for one interlayer or several interlayers to be provided between the figure and the polished layer.

In particular, the layer structure may also contain several layers, each having a figure or a shape corresponding to the figure.

The term “formed along the figure” may therefore mean that the polished layer conforms to the figure and runs adjacent to the figure. Additionally or alternatively, the expression “formed along the figure” may therefore mean that the polished layer conforms to the figure and runs alongside one or more interposed layers.

A thickness of the polished layer of up to 500 μm, more preferably up to 200 μm, more preferably up to 50 μm, more preferably up to 20 μm, more preferably up to 10 μm, more preferably up to 2 μm, more preferably up to 800 nm, more preferably up to 400 nm, more preferably up to 200 nm and even more preferably up to 100 nm is proposed. The thinner the polished layer, the greater the speed and economic viability of application thereof.

If titanium-doped quartz glass is used as the polished layer, it is possible to achieve a particularly small difference in the coefficients of thermal expansion of the primary layer of the substrate structure and of the polished layer. This is referred to in the jargon as good CTE matching.

For example, with a locally variable polished layer thickness, as can occur, for example, owing to a coating process and/or a fine figure correction, there will thus advantageously be lower stresses and lower CTE inhomogeneity.

With regard to the polished layer, the term “titanium-doped” preferably includes titanium co-doping.

A polished layer of titanium doped quartz glass is extremely similar to a substrate structure of titanium-doped quartz glass, and very similar to a substrate structure of a glass ceramic. It follows that the substrate structure and the polished layer will both react similarly when undergoing the same processing steps. For example, they are very efficiently collectively heat-treatable, such as temperable, or electron beam-compactable.

Titanium-doped quartz glass as polished layer can be used with a substrate structure containing titanium-doped quartz glass or glass ceramic. Therefore, the same material can be used as a polished layer for both types of substrate structure. This offers the added benefit that very similar production steps are applicable to both substrate structures. The result may therefore be a fall in production costs and a rise in process reliability.

The polished layer preferably contains a fine figure. The fine figure is preferably introduced into the polished layer by polishing. The fine figure enables the desired high imaging accuracy. It may be the case that the fine figure is not formed immediately in or on the polished layer, for example for reasons relating to production planning.

In one variant, the substrate structure may contain multiple TiO2-SiO2-containing primary layers having a different ratio of TiO2 to SiO2 (a different proportion of Ti or TiO2) than one another, where the primary layers follow one another and/or merge into one another in a direction perpendicular to the lateral face, wherein the concave figure intersects at least two primary layers. By providing the figure of this substrate structure with a polished layer of titanium-doped quartz glass, it is possible to avoid striae, with at the same time excellent matching of thermal expansion characteristics.

If the at least one primary layer contains Li2O—Al2O3-SiO2, roughness resulting from crystallites can be compensated for, with at the same time very well adjustably matching thermal expansion characteristics.

The substrate structure may optionally contain a layered microdeformation structure. The layered microdeformation structure is preferably set up and arranged for generation, in particular for controlled generation, of a locally variable deformation of the figure. One example of a layered microdeformation structure is described in DE 10 2017 213 900 A1.

It is optionally possible to provide at least one interlayer between the substrate structure and the polished layer. The interlayer may be formed in particular along the figure and/or adjacent to the polished layer.

For example, an interlayer may be set up to improve adhesion between the substrate structure and the polished layer. The same applies to a plurality of interlayers.

An interlayer may, for example, be set up to protect the substrate structure from the effect of a treatment step for treatment of the polished layer, such as for protection of the substrate structure from irradiation of the polished layer. The same applies to a plurality of interlayers.

An interlayer or a stratification of multiple interlayers may be set up to render a transition between the substrate structure and the polished layer nonreflective. For example, a refractive index of the substrate structure or at least a layer of the substrate structure adjacent to the figure, a respective refractive index of the at least one interlayer and a refractive index of the polished layer may be adjusted so as to increase or decrease in that sequence.

Optionally, the polished layer may have at least two part-layers. In a further development thereof, it may preferably be the case that a refractive index of the substrate structure or of at least one layer of the substrate structure adjacent to the figure and a respective refractive index of the part-layers of the polished layer are adjusted so as to increase or decrease successively in that sequence.

The polished layer may be blackened. For example, the polished layer may contain a region adjacent to a surface of the polished layer that faces away from the substrate structure, where a proportion of OH molecules in that region is lower than in the rest of the polished layer. There are measurement methods for measuring a shape of the figure and/or fine figure that provide more precise results in the presence of blackening.

An aftertreatment that leads, for example, to more accurate imaging, especially in EUV applications, is compaction, in particular electron beam compaction. It is accordingly optionally the case that the polished layer has, or the polished layer and the substrate structure have, been compacted in a region adjacent to the surface of the polished layer facing away from the substrate structure. For example, the polished layer may have been up to 5%, preferably up to 2% and even more preferably up to 1% compacted, based on a thickness of the polished layer.

For example, it may be the case that the polished layer, or the polished layer and the substrate structure, is compacted up to a penetration depth of up to 500 μm, more preferably up to a penetration depth of up to 200 μm, more preferably up to a penetration depth of up to 100 μm and even more preferably up to a penetration depth of preferably up to 50 μm. The term “penetration depth” is readily comprehended and may refer, for example, to penetration of compacting radiation and/or preferably to an extent of compaction.

The optical element may have different applications. For example, for an EUV application, it may be advantageous to position a reflection layer stack on a side of the polished layer remote from the substrate structure. The reflection layer stack is preferably set up for reflection of electromagnetic radiation which reaches a surface of the reflection layer stack remote from the polished layer. For applications and/or manufacturing processes, it may be advantageous to position the reflection layer stack adjacent to the polished layer. For other applications and/or production processes, it may be advantageous to position the reflection layer stack on the polished layer with at least one intervening interlayer. In this case, the layers are thus arranged, for example, in the following sequence: polished layer, interlayer, first reflection layer, second reflection layer, etc., or for example, in the following sequence: polished layer, first interlayer, second interlayer, first reflection layer, second reflection layer. Preference is given in particular to an interlayer called “SPL” in the jargon, for “substrate protection layer”, which can be designed, for example, to be virtually impermeable to an electron beam and/or to EUV radiation. For example, the reflection layer stack may contain an alternating sequence of a molybdenum-containing layer and a silicon-containing layer. The reflection stack may in particular have a concluding outer layer, referred to in the jargon as “top layer”, the material of which, for example, contains zirconium oxide.

The substrate structure may contain a cooling channel in order to keep the optical element within a desired temperature range during operation.

In a further aspect, an optical system is proposed for achievement of the object of the invention. This contains at least one optical element as proposed herein and/or including one of the optional developments proposed herein. Therefore, the optical system implements the benefits and properties of the optical element(s) used.

The optical system is preferably a projection optics unit of the projection exposure apparatus. However, the optical system may also be an illumination system. The projection exposure apparatus can be an EUV lithography apparatus. EUV stands for “extreme ultraviolet” and denotes a wavelength of the working light of between 0.1 nm and 30 nm. The projection exposure apparatus may also be a DUV lithography apparatus. DUV stands for “deep ultraviolet” and denotes a wavelength of the working light between 30 nm and 250 nm.

In a further aspect, a lithography apparatus is proposed for achievement of the object of the invention. This contains at least one optical element as proposed herein and/or including one of the optional developments proposed herein. Therefore, the lithography apparatus implements the benefits and properties of the optical element(s) used.

In a further aspect, a lithography apparatus is proposed for achievement of the object of the invention. This contains at least one optical system as proposed herein, or one which contains at least one optical element as proposed herein and/or including one of the optional developments proposed herein. Therefore, the lithography apparatus implements the benefits and properties of the optical element(s) used.

In a further aspect, a method of producing an optical element is proposed for achievement of the object of the invention. In a minimal configuration, the method proposed has steps a), b), and d) as follows.

Step a) comprises providing a substrate structure containing at least one primary layer containing SiO2, wherein the substrate structure has a lateral face.

With regard to terms such as “substrate structure”, “primary layer” or “lateral face”, reference is made in particular to the description of the proposed optical element.

Step b) comprises forming a convex or concave figure in and/or on the lateral face of the substrate structure.

Step d) comprises forming an up to 500 μm-thick polished layer along the figure, wherein the polished layer contains titanium doped quartz glass or TiO2-SiO2.

The forming of the polished layer in step d) preferably comprises: performing a coating process. Accordingly, the polished layer is preferably applied to the figure by coating rather than being formed by transformation in the substrate structure adjoining the figure. For example, coating can be more tolerant of the specific dimensions of roughness than transformation.

The providing in step a) preferably comprises: providing at least a primary layer of a glass ceramic, in particular an Li2O—Al2O3-SiO2-containing primary layer. According to the current state of knowledge, glass ceramic is a preferred substrate material for optical elements in EUV applications.

The providing in step a) preferably comprises: providing at least one primary layer containing TiO₂—SiO₂ or titanium-doped quartz glass. According to the current state of knowledge, titanium-doped quartz glass is a preferred substrate material for optical elements in EUV applications.

The substrate structure provided preferably contains several primary layers containing titanium doped quartz glass. The primary layers preferably have a different ratio of TiO2 to SiO2 than one another. In other words, a proportion by weight of titanium is different. The primary layers preferably adjoin one another and/or preferably merge into one another. The primary layers preferably follow one another in a direction perpendicular to the lateral face. In other words, in a direction perpendicular to the lateral face, the substrate structure preferably has a varying, preferably alternating, proportion by weight of titanium to the rest of the material.

The forming of the figure in step b) preferably includes forming of the figure so as to intersect at least two of the primary layers of different titanium content. The primary layers are therefore preferably aligned parallel to the lateral face, so as to achieve preferred thermal expansion characteristics. If the primary layers are thin based on a depth of the figure, it is possible to achieve desired uniform thermal expansion characteristics of the primary layers relative to one another.

The providing in step a) preferably includes, after the providing of the several TiO2-SiO2-containing primary layers: preforming the provided substrate structure by arranging the substrate structure on a negative mold with supply of heat.

Optionally, the method may include, between forming the figure in step b) and forming the polished layer in step d): forming at least one interlayer along the figure. In this case, preferably the polished layer in step d) is formed adjacent to the interlayer or one of the interlayers furthest away from the substrate structure. A wide variety of different interlayers are feasible for a wide range of different applications and/or production methods.

In a preferred option, in steps a), c) and d), a refractive index of the substrate structure or at least a layer of the substrate structure adjacent to the figure, a respective refractive index of the at least one interlayer and a refractive index of the polished layer are adjusted so as to increase or decrease in that sequence. By virtue of increasing or decreasing refractive indices from the substrate structure to the polished layer, for example, a figure measurement can be conducted without reflection. The same applies to a preferred option in which, in steps a) and d), a refractive index of the substrate structure or of at least one layer of the substrate structure adjacent to the figure and a respective refractive index of part-layers of the polished layer are adjusted so as to increase or decrease successively in that sequence.

The forming of the polished layer in step d) preferably includes: e) forming the polished layer by thermal evaporation, wherein the evaporation object used is a TiO2-SiO2-containing source material, f) forming the polished layer by ion beam sputtering, wherein the sputtering target used is a TiO2-SiO2-containing source material, g) directly depositing the polished layer on the figure formed on the substrate structure by flame hydrolysis, h) soot deposition of a soot layer on the substrate structure by flame hydrolysis, k) forming the polished layer by sintering the or a soot layer and/or n) depositing TiO2-SiO2-containing particles of a sol-gel provided on the substrate structure. For economic reasons, it is particularly preferable to select and employ exactly one of the abovementioned methods of forming the polished layer. In special cases, in particular if the polished layer is formed as a polished layer arrangement, a combination of at least two of the above methods may be advantageous, in particular successively in time.

The forming of the polished layer in step d) preferably includes: e) forming the polished layer by thermal evaporation, wherein the evaporation object used is a TiO2-SiO2-containing source material.

The forming of the polished layer in step d) preferably includes: f) forming the polished layer by ion beam sputtering, wherein the sputtering target used is a TiO2-SiO2-containing source material.

In the case of forming of the polished layer by ion beam sputtering in step f), and also in the case of forming of the polished layer by thermal evaporation in step e), a titanium content in the source material is preferably higher than in the polished layer formed or to be formed. With this option, it is possible, for example, to react to process parameters that cause a lower evaporation rate of the titanium.

In the case of forming of the polished layer by ion beam sputtering in step f), and also in the case of forming of the polished layer by thermal evaporation in step e), preferably two source materials may be used as evaporation objects or as sputtering targets, where the two source materials have different proportions of TiO2. With this option, it is possible, for example, to react to process parameters that could lead to a change in the titanium concentration in an evaporation chamber or sputtering chamber over time.

The forming of the polished layer in step d) preferably includes: g) directly depositing the polished layer on the figure formed on the substrate structure through flame hydrolysis. In the case of direct separation, a flame is preferably directed at an object at a short distance. In this case, the object is preferably the figure or an interlayer formed on the figure or a polished layer portion. For example, the object may be heated locally to at least 1400° C.

The direct deposition in step g) preferably includes several direct deposition operations. For example, it is possible first to provide a direct deposition to the figure of the substrate structure or an interlayer formed on the figure in order to form a first polished layer portion, then a direct deposition to the first polished layer portion in order to form a second polished layer portion, and so forth. Thereby, two or more polished layer portions can be deposited one on top of another.

The direct deposition of the polished layer in step g) preferably includes:
discontinuous scanning of a surface of the figure,
discontinuous scanning of an interlayer formed along the figure,
discontinuous scanning of a portion of the polished layer formed along the figure,
continuous scanning of the surface of the figure,
continuous scanning of an interlayer formed along the figure, and/or
continuous scanning of a portion of the polished layer formed along the figure,
   with radiation for local heating of a section of the surface, and deposition of the polished layer by directing the hydrolysis flame onto the locally heated section.

Discontinuous scanning can be referred to as sampling. In these cases, it may be the case that the radiation, which may be a laser radiation, irradiates a defined local section of the figure or of a layer formed on the figure. This heats up said local section to a target temperature. Then the hydrolysis flame is directed onto this local section in order to deposit the polished layer or at least a portion of the polished layer onto this local section. While the pyrolysis flame is directed at this heated local section, it is preferably the case that the radiation heats up the next local section.

Continuous scanning can be referred to as sweeping. In these cases, it may be the case that the radiation, which may be a laser radiation, irradiates a defined section of the figure or of a layer formed on the figure, with continuous alteration of the section. The orientation of the hydrolysis flame follows the radiation with a small time delay. Thus, directing the hydrolysis flame onto the heated section results in deposition of the polished layer or part of the polished layer.

The forming of the polished layer in step d) preferably includes: h) soot deposition of a soot layer on the substrate structure through flame hydrolysis.

The forming of the polished layer in step d) preferably includes, after the soot deposition in step h): k) forming the polished layer by sintering the soot layer.

The forming of the polished layer in step d) preferably includes: i) soot deposition of a soot.

The forming of the polished layer in step d) preferably includes, after the soot deposition in step i): j) shaping of a soot layer from the soot onto the substrate structure.

The forming of the polished layer in step d) preferably includes, after the forming of the soot layer in step j): k) forming the polished layer by sintering the soot layer.

These steps h), i), j) and k) can be combined and/or used differently, including periods of each, to form the polished layer in step b). Through soot deposition and the subsequent steps, particularly fine adjustment of the composition of the polished layer is possible.

The forming of the soot layer in step j) preferably includes: pressing the soot onto the substrate structure. Pressing the soot can reduce inclusions, for example, in order for example to establish more uniform thermal expansion characteristics.

The forming of the soot layer in step j) preferably includes:
mixing the soot with a binder,
shaping the soot layer, in particular by 3D printing and/or by casting and/or via spin-coating of the mixture of soot and binder, and
removing the binder from the soot layer, in particular by dissolving the binder using a solvent and/or burning the binder.

This process step improves shapability of the soot layer.

The soot deposition preferably involves depositing a soot containing the TiO2-SiO2 in the ratio of the polished layer. The ratio may state a weight ratio or molar ratio of the TiO2 to the SiO2 and/or to the non-TiO2 portion of the polished layer. Thus, the desired ratio of TiO2 to SiO2 is obtained directly.

The soot deposition preferably involves depositing a soot in which the ratio of TiO₂ to SiO₂ is lower than in the polished layer. In that case, the method preferably includes, prior to the sintering in step k): doping the soot layer with Ti. Alternatively, the titanium may be introduced into the polished layer after the sintering.

The forming of the polished layer in step d) preferably includes: 1) providing a sol-gel in which particles containing TiO2-SiO2 are formed, and n) depositing particles of the sol-gel on the substrate structure. Sol-gel deposition is a further advantageous method of forming the polished layer. In this process, titanium-doped quartz glass can be applied directly as polished layer. This process may be particularly economically favorable under some circumstances.

The forming of the polished layer in step d) preferably includes: m) providing a sol-gel in which particles are formed, wherein the ratio of TiO2 to SiO2 in the particles is lower than in the polished layer (less Ti in particles than Ti in polished layer), n) depositing particles of the sol-gel on the substrate structure, and o) doping the deposited particles of the sol-gel with Ti. Sol-gel deposition is a further advantageous method of forming the polished layer. In this process, the titanium doping can be subsequently applied to the quartz glass to form the polished layer. This process may result in particularly precisely adjustable doping values under some circumstances.

The formation of the polished layer after the depositing in step n) or in particular after the doping in step o) preferably includes: p) forming the polished layer by sintering the deposited or the deposited and doped particles. Thereby, a particularly uniform polished layer with particularly small inclusions can be formed.

The forming of the polished layer in step d) preferably includes: varying a ratio of TiO2 to SiO2, especially along a local perpendicular to the figure. Because the titanium content affects the thermal expansion characteristics of the polished layer, it is advantageous in the case of particular configurations and/or applications with uneven thermal stress, for example, to adjust the titanium content unevenly.

The method preferably includes, after the forming of the polished layer in step d): q) forming a convex or concave fine figure, in particular by fine polishing of the polished layer formed. The fine figure advantageously defines the roughness of the surface of the optical element and hence, for example, the achievable imaging resolution.

The method preferably includes, after the forming of the polished layer in step d) or the forming of the fine figure in step q): r) blackening of the polished layer, in particular by reducing a proportion of OH molecules in the polished layer. Blackening is advantageous in particular for some manufacturing steps, such as surveying of the fine figure, because reflections at interfaces between the polished layer and the substrate structure or an intervening interlayer can be reduced and/or avoided.

The blackening of the polished layer in step r) preferably includes: flushing the polished layer with fluid that releases hydrogen molecules, hydrogen plasma and/or a hydrogen to the polished layer.

The blackening of the polished layer in step r) preferably includes: irradiating the polished layer, in particular with short-pulse laser irradiation, ion beams, electron beams, X-radiation and/or neutron radiation. The methods mentioned are effective and precisely controllable blackening methods.

The method after the blackening in step r) preferably includes: s) shape testing of the fine figure. The shape testing of the fine figure can be used to monitor and document the desired imaging accuracy.

The method preferably includes, after the shape testing in step s): t) oxidizing the polished layer, in particular through heat treatment, flushing with oxygen or an oxygen-releasing fluid and/or implanting oxygen ions. The oxidizing can in particular reverse blackening, for example for controlled adjustment of reflection properties. The oxidizing can prevent OH molecules from diffusing out of the substrate structure into the polished layer in the course of operation of the optical element over the service life and hence leading to a growing figure defect.

The method preferably includes, after the forming of the polished layer in step d), the forming of the fine figure in step q), the blackening in step r), the shape testing in step s) or the oxidizing in step t): u) compacting the polished layer, in particular with electron beam compaction. Thereby, controlled adjustment of a hardness of the polished layer and/or a geometry of the polished layer, in particular a geometry of the fine figure, is possible.

The provision in step a) preferably includes: providing a layered microdeformation structure in the substrate structure, wherein the layered microdeformation structure is set up and arranged for (controlled) generation of a locally variable deformation of the figure. The microdeformation layer can be used to adjust a geometry of the figure or ultimately a reflective geometry in the operation of the optical element.

The method preferably includes, after the forming of the polished layer in step d), the forming of the fine figure in step q), the blackening in step r), the shape testing in step s), the oxidation in step t) and/or the compacting in step u): v) forming a layer impermeable to an electron beam on the polished layer, and/or w) forming a reflection layer stack which is set up to reflect electromagnetic radiation incident on a surface of the reflection layer stack that faces away from the polished layer.

In a further aspect, an optical element is proposed that has been produced by the proposed method of producing an optical element, has the properties thereof, has been produced according to one of the proposed modifications and/or has the properties of an optical element according to one of the proposed modifications of the production method.

An optical element according to one of the aspects of the invention is preferably an optical element for use in an EUV lithography apparatus and has in particular been set up and/or designed and/or manufactured accordingly.

“A” or “an” in the present context should not necessarily be regarded as a restriction to exactly one element. Instead, multiple elements, for example two, three or more, may also be provided. Any other numeral used here should also not be understood as a restriction to exactly the stated number of elements. Instead, unless indicated otherwise, numerical variances upward and downward are possible.

The embodiments and features described for the optical system apply correspondingly to the proposed method, and vice versa.

Further possible implementations of the invention also comprise non-explicitly mentioned combinations of features or embodiments described hereinabove or hereinafter with regard to the exemplary embodiments. A person skilled in the art will also be enabled to add individual aspects as improvements or supplementations to the respective basic form of the invention.

Further advantageous configurations and aspects of the invention are the subject of the dependent claims and of the exemplary embodiments of the invention that are described hereinafter. The invention is elucidated in detail hereinafter by preferred embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic cross section through an optical element in one embodiment;

FIG. 3 shows a schematic cross section through an optical element in a second embodiment;

FIG. 4 shows a schematic cross section through an optical element in a third embodiment;

FIG. 5 shows a schematic cross section through an optical element in a fourth embodiment;

FIG. 6 shows a schematic cross section through an optical element in a fifth embodiment;

FIG. 7 shows a schematic cross section through an optical element in a sixth embodiment;

FIG. 8 shows a schematic cross section through an optical element in a seventh embodiment; and

FIG. 9 shows a flow diagram for a production process according to one embodiment.

### DETAILED DESCRIPTION

In the figures, identical, analogous or functionally identical elements have been given the same reference symbols, unless stated otherwise. Furthermore, it should be noted that the illustrations in the figures are not necessarily true to scale.

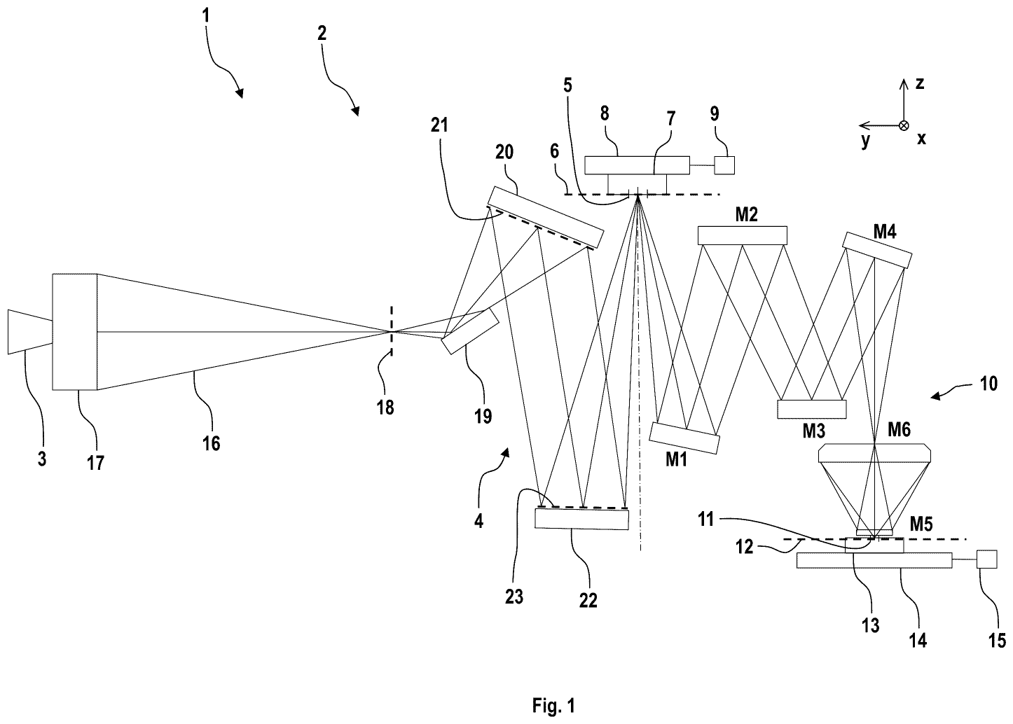

FIG. 1 shows one embodiment of a projection exposure apparatus 1 (lithography apparatus), in particular an EUV lithography apparatus. One design of an illumination system 2 of the projection exposure apparatus 1 has, in addition to a light or radiation source 3, an illumination optics unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable via a reticle displacement drive 9, in particular in a scanning direction.

FIG. 1 depicts, by way of elucidation, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction in FIG. 1 runs in the y direction y. The z-direction z runs perpendicularly to the object plane 6.

The projection exposure apparatus 1 comprises a projection optics unit 10. The projection optics unit 10 serves to image the object field 5 into an image field 11 in an image plane 12. The image plane 12 runs parallel to the object plane 6. Alternatively, a non-0° angle between the object plane 6 and the image plane 12 is also possible.

A structure on the reticle 7 is imaged onto a light-sensitive layer of a wafer 13 disposed in the region of the image field 11 in the image plane 12. The wafer 13 is held by a wafer holder 14. The wafer holder 14 is displaceable via a wafer displacement drive 15, in particular in the y direction y. The displacement, firstly, of the reticle 7 via the reticle displacement drive 9 and, secondly, of the wafer 13 via the wafer displacement drive 15 may be mutually synchronized.

The light source 3 is an EUV radiation source. The light source 3 emits in particular EUV radiation 16, which is also referred to below as used radiation, illumination radiation or illumination light. In particular, the used radiation 16 has a wavelength in the range between 5 nm and 30 nm. The light source 3 may be a plasma source, for example an LPP (laser produced plasma) source or a GDPP (gas discharge produced plasma) source. It can also be a synchrotron-based radiation source. The light source 3 may be a free electron laser (FEL).

The illumination radiation 16 emanating from the light source 3 is focused by a collector 17. The collector 17 can be a collector having one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 may represent a separation between a radiation source module, comprising the light source 3 and the collector 17, and the illumination optics unit 4.

The illumination optics unit 4 comprises a deflection mirror 19 and, disposed downstream thereof in the beam path, a first facet mirror 20. The deflection mirror 19 may be a planar deflection mirror or, alternatively, a mirror with a beam-influencing effect that goes beyond the purely deflecting effect. Alternatively or additionally, the deflection mirror 19 may be in the form of a spectral filter, which separates a used light wavelength of the illumination radiation 16 from extraneous light of a different wavelength. If the first facet mirror 20 is arranged in a plane of the illumination optics unit 4 which is optically conjugate to the object plane 6 as a field plane, it is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 may take the form of macroscopic facets, in particular rectangular facets or facets with an arc-shaped or part-circular edge contour. The first facets 21 may take the form of planar facets or, in an alternative to that, convexly or concavely curved facets.

As is known for example from DE 10 2008 009 600 A1, the first facets 21 themselves may each also be composed of a multiplicity of individual mirrors, in particular a multiplicity of micromirrors. The first facet mirror 20 may take the form of a microelectromechanical system (MEMS system) in particular. For details, reference is made to DE 10 2008 009 600 A1.

The illumination radiation 16 travels horizontally, i.e. in the y-direction y, between the collector 17 and the deflection mirror 19.

In the beam path of the illumination optics unit 4, a second facet mirror 22 is disposed downstream of the first facet mirror 20. If the second facet mirror 22 is disposed in a pupil plane of the illumination optics unit 4, it is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or alternatively may be facets composed of micromirrors. For details in this regard, reference is likewise made to DE 10 2008 009 600 A1.

The second facets 23 may have planar or, alternatively, convexly or concavely curved reflection surfaces.

The illumination optics unit 4 thus forms a doubly faceted system. This fundamental principle is also referred to as a fly's eye integrator.

It may be advantageous to arrange the second facet mirror 22 not exactly in a plane that is optically conjugate to a pupil plane of the projection optics unit 10. In particular, the second facet mirror 22 may be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment (not illustrated) of the illumination optics unit 4, a transfer optics unit contributing in particular to the imaging of the first facets 21 into the object field 5 may be arranged in the beam path between the second facet mirror 22 and the object field 5. The transfer optics unit may have exactly one mirror or alternatively two or more mirrors, which are arranged one behind another in the beam path of the illumination optics unit 4. The transfer optics unit may in particular comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20 and the second facet mirror 22.

In a further embodiment of the illumination optics unit 4, the deflection mirror 19 may also be omitted, and so the illumination optics unit 4 can then have exactly two mirrors downstream of the collector 17, specifically the first facet mirror 20 and the second facet mirror 22.

The imaging of the first facets 21 into the object plane 6 with the second facets 23 or using the second facets 23 and a transfer optics unit is regularly only approximate imaging.

The projection optics unit 10 comprises a plurality of mirrors Mi that are numbered consecutively in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The projection optics unit 10 is a doubly obscured optics unit. The penultimate mirror M5 and the last mirror M6 each have a passage opening for the illumination radiation 16. The projection optics unit 10 has an image-side numerical aperture that is greater than 0.5 and may also be greater than 0.6 and may be, for example, 0.7 or 0.75.

Reflection surfaces of the mirrors Mi may take the form of free-form surfaces without an axis of rotational symmetry. Alternatively, the reflection surfaces of the mirrors Mi may be designed as aspheric surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, in particular with alternating layers of molybdenum and silicon.

The projection optics unit 10 has a large object-image offset in the y-direction y between a y coordinate of a center of the object field 5 and a y coordinate of the center of the image field 11. This object-image offset in the y-direction y can be of approximately the same magnitude as a z separation between the object plane 6 and the image plane 12.

In particular, the projection optics unit 10 may have an anamorphic design. In particular, it has different imaging scales ßx, ßy in the x- and y-directions x, y. The two imaging scales ßx, ßy of the projection optics unit 10 are preferably (ßx, ßy)=(+/−0.25, +/−0.125). A positive imaging scale ß means imaging without image inversion. A negative sign for the imaging scale ß means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or can differ, depending on the embodiment of the projection optics unit 10. Examples of projection optics units with different numbers of such intermediate images in the x-direction x and y-direction y are known from US 2018/0074303 A1.

One of the second facets 23 in each case is assigned to exactly one of the first facets 21 for formation of a respective illumination channel for illumination of the object field 5. In particular, this can result in illumination according to the Köhler principle. The far field is broken down into a multitude of object fields 5 with the aid of the first facets 21. The first facets 21 create a plurality of images of the intermediate focus on the second facets 23 respectively assigned thereto.

The first facets 21 are each imaged onto the reticle 7 by an assigned second facet 23 with images overlaid over one another for the purpose of illuminating the object field 5. The illumination of the object field 5 is in particular of maximum homogeneity. It preferably has a uniformity error of less than 2%. Field uniformity can be achieved by the overlying of different illumination channels.

An arrangement of the second facets 23 can geometrically define the illumination of the entrance pupil of the projection optics unit 10. By selection of the illumination channels, in particular the subset of the second facets 23 that guide light, it is possible to adjust the intensity distribution in the entrance pupil of the projection optics unit 10. This intensity distribution is also referred to as illumination setting or illumination pupil filling.

A likewise preferred pupil uniformity in the region of portions of an illumination pupil of the illumination optics unit 4 that are illuminated in a defined manner can be achieved by a redistribution of the illumination channels.

Further aspects and details of the lighting of the object field 5 and in particular of the entrance pupil of the projection optics unit 10 are described hereinafter.

The projection optics unit 10 may have in particular a homocentric entrance pupil. The latter may be accessible. It can also be inaccessible.

The entrance pupil of the projection optics unit 10 regularly cannot be exactly illuminated with the second facet mirror 22. In the case of imaging by the projection optics unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area constitutes the entrance pupil or an area conjugate thereto in real space. In particular, this area exhibits finite curvature.

It may be the case that the projection optics unit 10 has different positions of the entrance pupil for the tangential beam path and for the sagittal beam path. In this case, an imaging element, in particular an optical component part of the transfer optics unit, should be provided between the second facet mirror 22 and the reticle 7. With the aid of this optical element, the different position of the tangential entrance pupil and of the sagittal entrance pupil can be taken into account.

In the arrangement of the components of the illumination optics unit 4 shown in FIG. 1, the second facet mirror 22 is disposed in an area conjugate to the entrance pupil of the projection optics unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

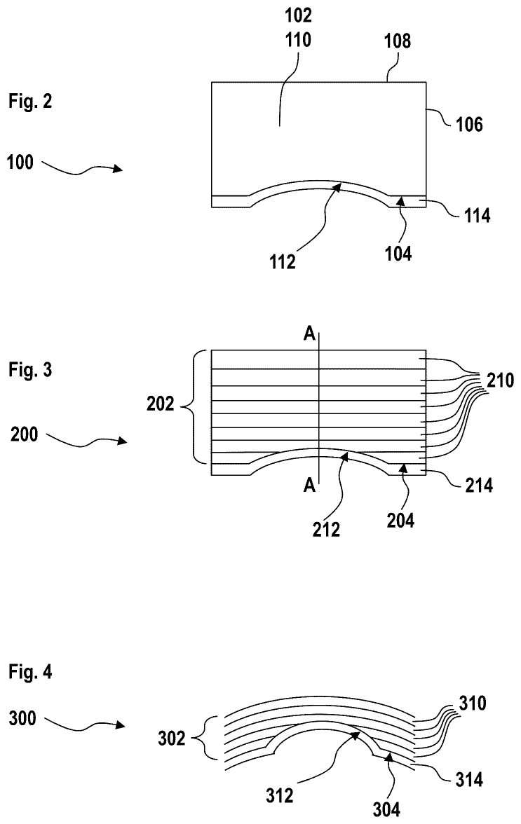

FIG. 2 shows an optical element 100 in a first embodiment.

The optical element 100 is, for example, one of the mirrors Mi.

The optical element 100 has a substrate structure 102. The substrate structure 102 is made of a glass ceramic, for example from “Zerodur”, which is a material of the Li2O—Al2O3-SiO2 type.

The substrate structure 102 has a first lateral face 104, and edge surfaces 106 and a further lateral face 108. In the first embodiment, the substrate structure 102 has a single primary layer 110.

A concave FIG. 112 is formed in the first lateral face 104. For example, the FIG. 112 in the present context has a roughness resulting from structures with a lateral period of about 100 nm.

A polished layer 114 is applied to the lateral face 104 with the FIG. 112. The polished layer 114 is made of titanium-doped quartz glass.

In the first embodiment, the figure is already designed as a fine figure, and the polished layer 114 is applied with a thickness of 100 nm. In other words, because the polished layer 114 is designed to compensate for the roughness, the polished layer may be very thin. This is advantageous because any slight differences in the thermal expansion characteristics of the substrate structure 102 and the polished layer 114 thus carry less weight.

FIG. 3 shows an optical element 200 in a second embodiment.

In contrast to the first embodiment, a substrate structure 202 has several primary layers 210. The primary layers 210 are formed one on top of another from titanium-doped quartz glass.

A FIG. 212 is formed in the substrate structure 202 so that the FIG. 212 intersects at least two primary layers 210. Along the FIG. 212, a polished layer 214 is likewise formed from titanium-doped quartz glass.

Otherwise, reference is made to the first embodiment.

FIG. 4 shows an optical element 300 in a third embodiment. In contrast to the second embodiment, the primary layers 310 of the substrate structure 302 are subjected to preliminary bending by a forming method; they are therefore, for example, roughly in the shape of a ball cup.

This type of substrate structure can be obtained by a method called “slumping” in the jargon. For this purpose, a substrate structure is first provided as in the second embodiment, i.e. with flat primary layers. This is then disposed on a negative mold in an oven. With an empirically determinable temperature-time profile, the material flows so as to establish the curved shape of the substrate structure 302.

A concave FIG. 312 is formed in a concave-curved lateral face 304. The FIG. 312 is more curved than the lateral face 304.

A polished layer 314 is formed along the FIG. 312.

Otherwise, reference is made to the above embodiments.

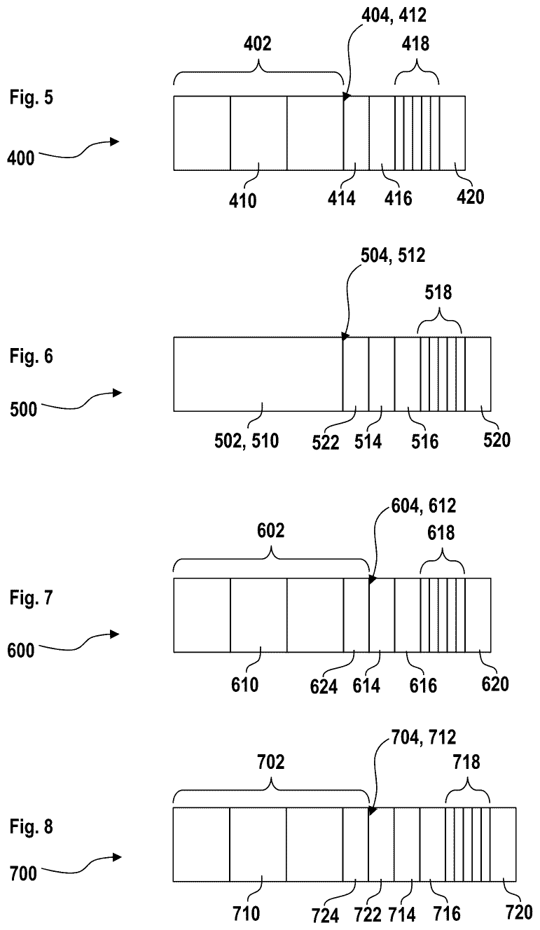

There follows a description of four embodiments with reference to a profile along the line marked with A-A in FIG. 3. In FIGS. 5 to 8, the concave curvature that exists cannot be seen for reasons of magnification.

FIG. 5 shows an optical element 400 in a fourth embodiment. This contains a substrate structure 402 having multiple primary layers 410 of titanium doped quartz glass. A concave FIG. 412 is recessed from a lateral face 404, cutting through several primary layers 410. Along the FIG. 412, the polished layer 414 is formed from titanium-doped quartz glass.

A protective layer 416 is formed on the polished layer 414 and is designed for blocking of EUV radiation. This protective layer 416 is an interlayer.

A reflection layer stack 418 is disposed on a surface of the protective layer 416 facing away from the polished layer 414. This comprises multiple reflection layers that are alternately formed from molybdenum and silicon.

Finally, an outer layer 420 of zirconium oxide is applied.

Otherwise, reference is made to the above embodiments.

FIG. 6 shows an optical element 500 in a fifth embodiment. This comprises, in contrast to the fourth embodiment, firstly the substrate structure 502 having a primary layer 510 of glass ceramic, and secondly, between the substrate structure 502 and the polished layer 514, a protective layer 522 which is an interlayer.

The protective layer 522 is designed to prevent a flow of electrons between the substrate structure 502 and the polished layer 514.

Otherwise, reference is made to the above embodiments.

FIG. 7 shows an optical element 600 in a sixth embodiment.

The substrate structure 602 has firstly multiple primary layers 610 of titanium-doped quartz glass, and secondly a layered microdeformation structure 624.

The layered microdeformation structure 624 is set up and arranged for controlled generation of a locally variable deformation of the figure. In the present example, the layered microdeformation structure 624 has at least four layers that are not shown in detail, namely two conductor layers which accommodate electrical conductors, a piezoelectric layer which includes piezo actuators, and a deformer layer of titanium-doped quartz glass, which is deformed by the piezo actuators. As becomes clear, for example, from DE 10 2017 213 90 A1, more layers may be present and/or another layer present may be used as a conductor layer. Otherwise, reference is made to the above embodiments.

FIG. 8 shows an optical element 700 which contains, in this sequence: multiple primary layers 710 which, together with a microdeformation layer 724, form a substrate structure 702, a protective layer 722 against electron transmission, the polished layer 714, a protective layer 716 against EUV radiation, and a reflection layer stack 718 which is completed by an outer layer 720.

Otherwise, reference is made to the above embodiments.

There follows a description of a production process for producing one of the optical systems 100, 200, 300, 400, 500, 600, 700.

The production process in a further embodiment includes at least the following steps:
Step a) providing the substrate structure 102 . . . 702,
Step b) forming the FIG. 112 . . . 712, and
Step d) forming the polished layer 114 . . . 714.

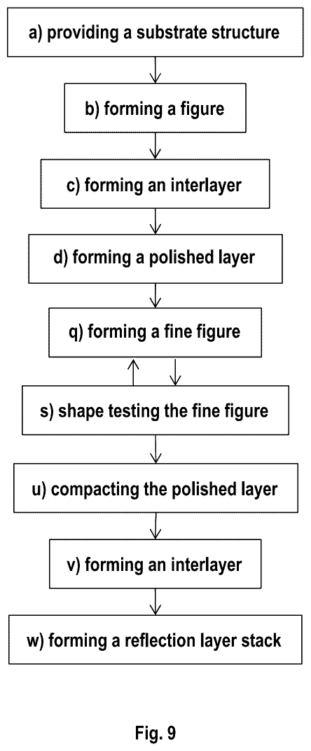

The production process in a further embodiment, including optional steps, includes the following steps (see FIG. 9):
Step a) providing the substrate structure 102 . . . 702,
Step b) forming the FIG. 112 . . . 712,
Step c) forming the interlayer 522, 722,
Step d) forming the polished layer 114 . . . 714,
Step q) forming the fine figure,
Step s) shape testing the fine figure
   where steps q) and s) in particular may be repeated as required,
Step u) compacting the polished layer,
Step v) forming the interlayer 416 . . . 716, and
Step w) forming the reflection layer stack 418 . . . 718,
   including forming the outer layer 420 . . . 720.

Special features of the production process are discussed hereinafter in connection with the polished layer of titanium-doped quartz glass.

### Thermal Evaporation, Ion Beam Sputtering

The forming of the polished layer in step d) may therefore include:
e) forming the polished layer by thermal evaporation, wherein the evaporation object used is a TiO₂—SiO₂-containing source material, and/or
f) forming the polished layer by ion beam sputtering, wherein the sputtering target used is a TiO₂—SiO₂-containing source material.

Depending on the chosen process parameters, both processes result in faster evaporation of SiO₂ out of a source material than TiO₂. In particular in the case of a coating forming of a comparatively thick polished layer, precise adjustment of the Ti content is desired. This has the advantage that thermal expansion characteristics that match as closely as possible, called thermal matching in the jargon, and/or low interface reflection can be achieved.

It is suggested, for example, that the source material used, i.e. the material to be evaporated or the sputtering target, be a titanium doped quartz glass with a higher Ti content than the Ti content of the substrate to be vaporized. A Ti content in the source material is thus preferably higher than in the polished layer formed.

Some process parameters and evaporation devices or sputtering devices may result in gradual accumulation of titanium in the evaporator or a sputtering chamber. Therefore, it may be advantageous to use two vaporizers or two targets with different Ti concentration. Thereby, for example, a Ti mixing ratio can be adjusted with time. In other words, preference is given to using two source materials as evaporation objects or sputtering targets, where the two source materials have different proportions of TiO₂.

Forming the polished layer through thermal evaporation and/or ion beam sputtering has two advantages: firstly, it is possible to compensate for roughness resulting from striae and/or from crystallites crystallized from a glass ceramic. Secondly, it is possible to avoid undesirable reflection in a figure test by interferometry.

The methods mentioned are particularly suitable for forming or depositing the polished layer in one pass, where the polished layer may have a thickness of up to 10 μm.

### Direct Deposition

Forming the polished layer in step d) may include:
g) directly depositing the polished layer onto the figure formed on the substrate structure by flame hydrolysis.

Direct deposition is particularly advantageous if a polished layer thickness of thickness more than 10 μm is desired. In addition, direct deposition creates a comparatively dense layer, which facilitates processibility.

The method of direct deposition by flame hydrolysis is employed for production of a synthetic quartz glass. Existing experience can thus be utilized advantageously.

In flame hydrolysis, for example, a silicon-containing and optionally a titanium-containing precursor substance, such as tetraisopropyl orthotitanate, is burnt in hydrogen-oxygen gas, for example. This forms small glass particles in the flame.

In one option, the flame can be directed at a target or already deposited glass at a short distance. The surface of the substrate structure can reach, for example, at least 1400° C. or more.

Owing to the high temperatures, the method is advantageously usable for substrate structures containing or consisting of titanium-doped quartz glass.

In one option, the respective glass surface is heated a few μm deep with a laser directly before deposition. This can be accomplished, for example, in that a deposition burner discontinuously or continuously scans the surface and/or in that a laser beam runs ahead of the deposition burner. In order to keep the heat-affected zone small, a high scanning speed, an expanded two-dimensional laser beam and/or pulsed flat deposition are advantageously usable.

The direct deposition of the polished layer in step g) may thus include:
discontinuous (sampling) or continuous (sweeping) scanning of a surface of the layer structure or (a surface of) an already deposited portion of the polished layer with radiation for local heating of a section of the surface, and
depositing of the polished layer by directing the hydrolysis flame onto the locally heated section.

In one option, in pulsed surface deposition, for example, an ignitable mixture is introduced into a chamber and ignited by a laser beam or an ignition spark. It is advantageous that similar stratifications to those in the case of direct deposition of vitreous bodies are achievable. It is particularly advantageous here that a layer separation between two sublayers of the polished layer can be set well below the typical 200 μm for titanium doped quartz glass by empirically determining a low deposition rate. This preferably causes a shift in the interference patterns to higher frequencies, in particular to higher frequencies suitable for smoothing by stochastic processing.

The aim may alternatively be that of depositing the required total layer thickness of preferably 0.1-20 μm in a single step.

A deposition diameter is preferably set such that an overlap region in which lateral inhomogeneities can sometimes occur can be reduced to an efficiently correctable degree. Preferred deposition diameters are from 1 mm to a few cm, for example 5 cm.

### Soot Deposition

Generally speaking, a soot deposition involves directing a pyrolysis flame at an object or target at a greater distance than in the direct deposition described above. This object in the present case is in particular the figure formed in or on the substrate structure, an interlayer formed on the figure and/or an already positioned and/or deposited portion of the polished layer. In the case of soot deposition, the alignment and/or distance of the pyrolysis flame with respect to the object is adjusted such that a soot body is deposited on the object.

Thus, the forming of the polished layer in step d) preferably includes:
h) soot deposition of a soot layer on the substrate structure by flame hydrolysis.

Depending on the process parameters, the soot body can be deposited in a porous manner. Optionally, drying of the soot body may be included. Optionally, the soot of the soot body may have been doped. Optionally, doping of the soot body may be included. Optionally, glazing of the soot body may be included. Optionally, sintering of the soot body may be included. Optionally, vacuum sintering of the soot body may be included. Optionally, a combination and/or different sequence including repeats of these and/or further process steps may be envisaged.

Preferably, the forming of the polished layer in step d), in particular after the soot deposition in step h), includes:
k) forming the polished layer by sintering the soot layer.

In one embodiment, preheating of the substrate structure may be envisaged. For example, if the substrate structure is to be formed from titanium-doped quartz glass, preheating up to about 1500° C., preferably up to 1300° C., preferably up to 1250° C., more preferably up to 1100° C. and more preferably up to 1000° C. is envisaged. Tempering of the substrate structure during the forming of the figure between a fine grinding step and a fine figure adjustment may optionally be envisaged, where the substrate structure is heated up to about 1500° C., preferably up to 1300° C., preferably up to 1250° C., more preferably up to 1100° C. and more preferably up to 1000° C. The substrate structure, in the course of tempering during the forming of the figure and during preheating, is more preferably heated to the same temperature with a tolerance of +/−10%, preferably +/−5% and more preferably +/−1.5%.

Optionally, after the polished layer has been formed, tempering is envisaged, wherein the mirror blank is heated up to at least 1000° C., preferably up to at least 1100° C. and preferably up to at least 1300° C. and/or up to the material-dependent temperature which is called “anneal point” in the jargon. With this step, it is possible to adjust thermal expansion characteristics, a CTE and a CTE slope in the jargon, to a desired value.

If the substrate structure contains a glass ceramic, preheating may likewise be used. Lower temperatures are preferred here than in the substrate structure of titanium-doped quartz glass, where the actual temperature is preferably determined depending on the specific type of the glass ceramic and/or a pretreatment.

It may be that a glass ceramic (such as “Zerodur” from Schott) shows crystallization characteristics at a processing temperature, in particular at a sustained processing temperature, above 600° C. for example. This material-dependent behavior can be countered, for example, as follows. For example, in step a), the substrate structure of glass ceramic may be provided, where no crystallites or crystallites below an empirically determined lower limit are present in the glass ceramic. This is then followed, in step b), by mechanical processing and, in step d), by applying of the polished layer, where the substrate structure reaches a temperature above 650° C. for example. This is optionally followed by a preferred tempering or annealing operation in order to perform crystallization for the first time.

Alternatively, the forming of the polished layer in step d) may include:
superficially heating the substrate structure and/or an interlayer formed on the figure, in particular with an IR illuminator, and
then step h).

Thus, a change in thermal expansion characteristics can be limited to only a thin near-surface layer of the substrate structure made of titanium-doped quartz glass or glass ceramic.

If a reflection layer stack is subsequently formed along the polished layer, it is possible, for example, to use a difference in the thermal expansion characteristics of the reflection layers and/or of the lowermost reflection layer from the polished layer as a measure of a difference in the thermal expansion characteristics between the polished layer and a portion of the substrate structure at a distance from the polished layer. For example, it is possible to calculate a limit as the product of change in CTE and the penetration depth of the change.

For example, a soot density may be 0.1 to 0.5 times a density of the substrate structure. For example, depending on the desired thickness of the polished layer and/or density of the soot, a soot layer with a thickness of 10 μm to a maximum of 1 mm, preferably 20 μm to 800 μm, may be deposited, for example.

Optionally, the forming of the polished layer, in particular between steps h) and k), may include a smoothing and/or a precompaction with a rolling operation, a peeling operation and in particular a peeling operation with a spatula, with ultrasound, with radiation pressure (light pulses), by pressing with a ram shaped negatively or suitably inversely with respect to the figure or fine figure, and/or with cold isostatic pressing.

The smoothing may optionally be preceded or followed by: setting of a desired OH content, in particular based on a weight, by drying and/or flooding with at least one gas and/or at least one aqueous solution.

The smoothing may optionally be preceded or followed by: establishment of a desired doping by drying and/or flooding with at least one gas and/or at least one aqueous solution.

In a preferred variant, undoped quartz glass is first deposited in step h) in the course of soot deposition, and titanium doping is then undertaken. This can be used to avoid high- and medium-frequency titanium inhomogeneities, as can occur depending on the process parameters in the course of scanning or layer-by-layer deposition.

The sintering is preferably done by scanning or two dimensionally by laser or short-term IR irradiation. It is thus possible to minimize a heat load for the substrate. Optionally, as for example also in the course of deposition, the entirety or surface region can be preheated to an uncritical temperature in order to use pulse-like sintering with lower energy densities.

Multistep sintering and consolidation is optionally possible, such that largely pore-free compaction is achieved in a first step. In an optional next step, the glass can be melted once again with a short-pulse laser such that structural glass defects and/or pores are removed.

Particularly in the case of a substrate made of titanium-doped quartz glass, the entire coated mirror body can be heated to temperatures of, for example, 1000° C. to 1300° C. without a change in figures that critically influences the imaging properties and kept at that temperature for several hours or up to several days in order to achieve a polished layer which is impervious, has low stress levels and/or is free of structural defects to the desired degree. Thereafter, a tempering process is preferably conducted for establishment of a desired fictive temperature. With regard to this tempering process, reference is made to the disclosure of U.S. Pat. No. 10,732,519 A1. Optionally, a second tempering step is carried out at controlled rates below a fictive temperature according to the disclosure of EP 3 044 174 A1.

Optionally, a glass ball blasting operation and/or a hipping operation for surface compaction may be provided or connected downstream. Particularly in the case of glass ball blasting, a tempering process is advantageous for curing any depth damage.

It will be apparent that the aforementioned processes can also be used for deposition of pure quartz glass on titanium-doped quartz glass, quartz glass and glass ceramics.

Soot deposition separately from soot layer formation

The forming of the polished layer in step d) preferably includes:
i) soot deposition of a soot
j) shaping of a soot layer from the soot onto the substrate structure, and
k) forming the polished layer by sintering the soot layer.

In general terms, it may thus be the case that a deposition burner fires into a chamber without a target. Advantageously, only a single burner is used in order to rule out a variation in composition owing to differences between burners. For example, the soot is collected, mixed, pressed and sintered.

For example, a soot powder from a deposition process can be applied in a defined layer thickness and/or mass occupancy density to the figure formed in step 2) and/or the interlayer formed in layer 3). It is advantageous here that the substrate structure is not exposed to a thermal load as a result of preheating and/or deposition.

It is feasible that the forming of the soot layer in step j) includes:
pressing the soot onto the substrate structure.

Optional electrostatic charging of the substrate structure is particularly suitable for attracting powder. Excess powder is optionally removed here by gravity and/or blowing with a stream of air.

Also feasible is controlled application with a spreader and/or a vibrating membrane which is covered, for example, with powder from above.

Also further feasible is floating and/or emulsification of the powder in a liquid. Preferred liquids contain water, an alcohol, a nonpolar organic solvent, gels and/or a combination thereof. In a development, evaporation of a solvent may be envisaged, in particular with moderate heating and/or optional oxygen supply. Additionally or alternatively, ashing of any adhering organic residues, for example of an emulsifier or a gel former, may be envisaged, in particular with moderate heating and/or optional oxygen supply. In a development, drying of the powder and removing of organic residues may be envisaged, for example similarly to a process step for preparing for sintering.

The forming of the soot layer in step j) preferably includes:
mixing the soot with a binder,
shaping the soot layer, in particular by 3D printing and/or by casting and/or through spin-coating of the mixture of soot and binder, and
removing the binder from the soot layer, in particular by dissolving the binder using a solvent and/or burning the binder.

The soot deposition preferably involves depositing a soot containing the TiO2-SiO2 in the ratio of the polished layer.

The soot deposition preferably involves depositing a soot in which the ratio of TiO₂ to SiO₂ is lower than in the polished layer (less Ti in soot than Ti in polished layer), and
wherein the method, before the sintering in step k), includes:
doping the soot layer with Ti.

By 3D printing

It is suggested that forming of the polished layer in step d) includes:
i) soot deposition of a soot
j) shaping of a soot layer from the soot onto the substrate structure, and
k) forming the polished layer by sintering the soot layer.

It is suggested here that the forming of the soot layer in step j) preferably includes:
mixing the soot with a binder,
shaping the soot layer, in particular by 3D printing and/or by casting and/or through spin-coating of the mixture of soot and binder, and
removing the binder from the soot layer, in particular by dissolving the binder using a solvent and/or burning the binder.

In the case of use of 3D printing, for example, loose soot is mixed with an organic binder, such as by stirring. The soot may contain or consist of undoped quartz glass and/or titanium doped quartz glass. For this purpose, for example, it is possible to use the above-described deposition process.

The mass containing soot and binder is applied to the figure. Preferred application methods include 3D printing and/or casting. The binder then hardens. What is called the green body can optionally be processed mechanically. This is preferably followed by triggering of the binder, in particular with an organic solvent and/or by combustion, in particular by pyrolysis. The resulting soot body may be porous. Subsequently, the soot body is sintered, where shrinking may be envisaged.

It is proposed that these methods be used for deposition of a layer of quartz glass or titanium doped quartz glass of several micrometers in thickness on the substrate structure.

It is optionally possible to apply a thin layer of the powder-filled binder, for example by spin coating, to cure a polymer of the binder and subject it to ashing. This method is very material-conserving. An optional sintering operation is envisaged subsequently.

### Sol-Gel Method

Generally speaking, a layer of quartz glass and/or titanium-doped quartz glass is deposited in the sol-gel method.

The forming of the polished layer in step d) preferably includes:
l) providing a sol-gel in which particles containing TiO₂—SiO₂ are formed, and
n) depositing particles of the sol-gel on the substrate structure and/or an interlayer.

The forming of the polished layer in step d) preferably includes:
m) providing a sol-gel in which particles are formed, wherein the ratio of TiO₂ to SiO₂ in the particles is lower than in the polished layer (less Ti in particles than Ti in polished layer),
n) depositing particles of the sol-gel on the substrate structure, and
o) doping the deposited particles of the sol-gel with Ti.

The forming of the polished layer after the depositing in step n) or in particular after the doping in step o) preferably includes:
p) forming the polished layer by sintering the deposited or deposited and doped particles.

Depending on the process parameters, better adhesion and/or higher density and/or lower porosity of the material deposited in the 3D printing process may be desired. For this purpose, the following are suggested: a polished layer deposited during the 3D printing process by a laser sintering operation and/or heating of the mirror body to more than 1000° C.

### Further Advantageous Developments

The aforementioned methods can also be employed for production of an optical element containing at least one cooling channel.

If the substrate structure containing multiple primary layers of titanium-doped quartz glass is subjected to a tempering treatment with a hold temperature above 800° C. for example, preferably above 1000° C. for example, it is proposed that the coating be conducted preferably in a contact-bonded state and that the bonding be performed in one operation with the tempering treatment. Alternatively or additionally, it may be the case that only the lateral face 104 . . . 704 containing the FIG. 112 . . . 712 is coated, and the second lateral face 108 underside is processed after the coating. This is preferably followed by a contact-bonding operation and/or another fixing operation on and/or at the second lateral face 108. If a tempering treatment above 1200° C. is provided, it is preferable to dispense with the contact bonding, for example in order to save costs.

Preferably, providing of a spacer and/or a suitable shaping of the lateral faces 104 . . . 704 and 108 ensures controlled adaptation.

### Adjustment of the Refractive Index Step

In some configurations, there may be undesirable reflection between the polished layer and the substrate structure during an interference-based figure test. In particular, for such configurations, it is suggested to reduce a refractive index step, for example between the substrate structure and the polished layer.

A proposed option for reducing the refractive index step is to provide at least one further layer of defined thickness between the substrate structure and the polished layer.

It is suggested that the method, between forming the figure in step b) and forming the polished layer in step d), include:
c) forming at least one interlayer along the figure,
wherein the polished layer in step d) is formed adjacent to the interlayer or one of the interlayers furthest away from the substrate structure,
wherein, in steps a), c) and d), a refractive index of the substrate structure or at least a layer of the substrate structure adjacent to the figure, a respective refractive index of the at least one interlayer and a refractive index of the polished layer are adjusted so as to increase or decrease in that sequence.

It is suggested that the method in the forming of the polished layer in step d) include:
forming at least two part-layers of the polished layer,
wherein, in steps a) and d), a refractive index of the substrate structure or at least a layer of the substrate structure adjacent to the figure and a respective refractive index of the sublayers of the polished layer are adjusted so as to increase or decrease in that sequence.

It is possible to use an essentially known formula for calculation of an antireflection layer. It is thus preferably possible to distinctly reduce reflection at the boundary layer for the interferometer working wavelength.

Thereby, sharply defined edges and/or gradient transitions may be chosen. For example, it would be possible to vary the titanium content over the height of the applied layer or provide doping with a third material.

The forming of the polished layer in step d) preferably includes:
varying a ratio of TiO₂ to SiO₂, especially along a local perpendicular to the figure.

### Blackening of the Polished Layer

In some configurations, there may be undesirable reflection between the polished layer and the substrate structure during an interference-based figure test. For such configurations in particular, a sole measure or an additional antireflection measure proposed is permanent or temporary blackening of the polished layer.

The method, after the forming of the polished layer in step d) or the forming of the fine figure in step q), therefore preferably includes:
r) blackening of the polished layer, in particular by reducing a proportion of OH molecules in the polished layer.

For example, it is possible to utilize the fact that Ti3+ has high absorption. Titanium-doped quartz glass from a soot deposition process, for example after tempering to establish a desired coefficient of thermal expansion, can still achieve up to 50% reflection per cm of layer thickness on irradiation with a wavelength of 500 nm.

OH-richer quartz glass from direct deposition, for example titanium-doped quartz glass, is noticeably lighter in color since OH can provide the necessary oxygen for oxidation to Ti4+ in hot processes.

For desired suppression of interfacial reflection depending on a Fresnel reflection, it is proposed that at least an absorption of 50% be established for a working wavelength of the interferometer in the polished layer. The reference point here is preferably the polished layer after processing by polishing.

Absorption values of 50% or more, based on the working wavelength, can preferably be specifically adjusted by first optionally reducing the OH content in a near-surface layer having a thickness of a few hundred micrometers through tempering. For this purpose, the optical element 100 . . . 700, after step d), can be treated, for example, at temperatures of 700° C. to 900° C. for a period between one day and 7 days. This can be advantageously combined with, or performed simultaneously with, tempering to establish thermal expansion characteristics.

If tempering is performed to reduce the OH content after tempering in order to establish thermal expansion characteristics, it may be advantageous for some configurations not to exceed a temperature of, for example, 800° C. in the course of tempering in order to establish thermal expansion characteristics.

Thereafter, treatment is preferably effected in hot molecular hydrogen or hydrogen plasma.

The blackening of the polished layer in step r) thus preferably includes:
flushing the polished layer with fluid that releases hydrogen molecules, hydrogen plasma and/or a hydrogen to the polished layer.

Exact partial pressures and durations should be determined empirically and/or analytically on the basis of electronegativities.

According to first estimates on the part of the inventor, in particular, a temperature of 500° C. to 800° C. and/or a partial pressure of a few percent to 100% may be advantageously usable. From a safety point of view, it should be noted that a partial pressure above 100% may be employable during a pressure treatment such as a pressurized furnace treatment.

It is suggested that the high hydrogen concentration in the region of the polished layer be achieved in a controlled manner in this method step. According to a first estimate, a hydrogen concentration of 1e16 to 5e17 molecules per cm³ is advantageously employable under the aforementioned conditions.

In a further option, treatment in a pressurized furnace at a hydrogen concentration up to 1e20 is advantageously employable.

In order to adjust an inward diffusion rate of H2 to a reduction rate of Ti3+ to Ti4+, it is suggested that a periodically fluctuating partial H2 pressure be generated. For example, it would advantageously be possible to envisage a fluctuation with a period between 1 min and 20 minutes, preferably depending on the prevailing temperature. Thus, in a preferred development, a defined partial pressure may be established for a few minutes, for example for 5 minutes, until the desired content of OH in the interface of the polished layer is attained. Then the partial pressure is reduced to 0 and/or, depending on the prevailing temperature for the reduction, the temperature is adjusted upward or downward in a controlled manner. If the hydrogen in the polished layer or the interface layer thereof has fallen to virtually 0, the partial hydrogen pressure is preferably increased again. This method has the advantage that only very little hydrogen accumulates in the substrate.

It is not necessary to achieve homogeneous blackening in the thickness direction of the polished layer. It is suggested to use total absorption in the polished layer as the control variable for the process. Maximum blackening is likely to be achieved near the surface of the polished layer.

Additionally or alternatively to the inward diffusion of hydrogen, short pulse laser irradiation, ion implantation, electron beam treatment, X-ray treatment and/or neutron irradiation may also be envisaged. These methods have the advantage that the penetration depth can be well defined.

The blackening of the polished layer in step r) therefore preferably includes:
irradiating the polished layer, in particular through short-pulse laser irradiation, ion beams, electron beams, X-radiation and/or neutron radiation.

The method, after the blackening in step r), preferably includes:
s) shape testing of the fine figure.

For manufacturing reasons, it may be advantageous to remove the blackening prior to coating with a metallic reflection system diffuse again.

The method, after the shape testing in step s), may therefore include:
t) oxidizing the polished layer, in particular with heat treatment, flushing with oxygen or an oxygen-releasing fluid and/or implanting oxygen ions.

For example, a tempering treatment at 100° C. to 800° C., preferably at 300° C. to 600° C., and a duration of 6 hours to 6 days may be envisaged. This thermal treatment, parametrized according to the configuration, may be conducted without resulting in an unwanted change of figure.

In order to reduce a high Ti3+ content in a near-surface region of the polished layer, the method may envisage a tempering treatment at 700-1000° C. over several days. This causes diffusion of OH out of the interior of the substrate structure 102 . . . 702 toward the surface, such that the Ti3+ is oxidized. Accordingly, desired thermal expansion characteristics can be established.

Alternatively, it is also possible to use treatment in oxygen or implantation of oxygen ions.

### ICE-T or Electron Beam Compaction

In order to compress the polished layer and/or if tempering has not been carried out or has not been carried out sufficiently because of a trade-off, the method may envisage an electron beam compaction, referred to in the art as “ICE-T”

Thus, the method, after the forming of the polished layer in step d), the forming of the fine figure in step q), the blackening in step r), the shape testing in step s) or the oxidation in step t), may include:
u) compacting the polished layer, in particular through electron beam compaction and/or photon beam compaction.

The penetration depth is adjustable, for example, via an electron energy or photon energy; an electron energy or photon energy appropriate for a penetration depth of 5-50 μm is preferably established. It is optionally the case that only the polished layer or only a portion of the polished layer is compacted. It is optionally also feasible to compact a portion of the substrate structure.

The above description of exemplary embodiments has been given by way of example. From the disclosure given, those skilled in the art will not only understand the present invention and its attendant advantages but will also find apparent various changes and modifications to the structures and methods disclosed. The applicant seeks, therefore, to cover all such changes and modifications as fall within the spirit and scope of the invention, as defined by the appended claims, and equivalents thereof.

### LIST OF REFERENCE SYMBOLS

1 projection exposure apparatus
2 illumination system
3 light source
4 illumination optics unit
5 object field
6 object plane
7 reticle
8 reticle holder
9 reticle displacement drive
10 projection optics unit
11 image field
12 image plane
13 wafer
14 wafer holder
15 wafer displacement drive
16 illuminating radiation
17 collector
18 intermediate focal plane
19 deflection mirror
20 first facet mirror
21 first facet
22 second facet mirror
23 second facet
100 optical element
102 substrate structure
104 lateral face
106 peripheral face
108 lateral face
110 primary layer
112 FIG.
114 polished layer
200 optical element
202 substrate structure
204 lateral face
210 primary layer
212 FIG.
214 polished layer
300 optical element
302 substrate structure
304 lateral face
310 primary layer
312 FIG.
314 polished layer
400 optical element
402 substrate structure
404 lateral face
410 primary layer
412 FIG.
414 polished layer
416 protective layer
418 reflection layer stack
420 outer layer
500 optical element
502 substrate structure
510 primary layer
514 polished layer
522 protective layer
600 optical element
602 substrate structure
610 primary layer
624 microdeformation layer
700 optical element
702 substrate structure
710 primary layer
714 polished layer
716 protective layer
718 reflection layer stack
720 outer layer
722 protective layer
724 microdeformation layer
M1 mirror
M2 mirror
M3 mirror
M4 mirror
M5 mirror
M6 mirror

What is claimed is:

1. An optical element comprising:
a substrate structure containing a plurality of TiO₂—SiO₂-containing primary layers having mutually differing ratios of TiO₂ to SiO₂, where the primary layers follow one another and/or merge into one another in a thickness direction of the substrate structure, and where a lateral face of the substrate structure has a concave figure that intersects at least two of the primary layers, and
an at most 500 μm-thick polished layer containing TiO₂—SiO₂, formed along the figure.

2. The optical element as claimed in claim 1,
containing at least one primary layer of Li₂O—Al₂O₃—SiO₂.

3. The optical element as claimed in claim 1, including
a layered microdeformation structure in the substrate structure, wherein the layered microdeformation structure is configured and arranged to generate a locally variable deformation of the figure.

4. The optical element as claimed in claim 1, including
at least two part-layers of the polished layer,
wherein a refractive index of the substrate structure or of at least one layer of the substrate structure adjacent to the figure and a respective refractive index of the part-layers of the polished layer are adjusted so as to increase or decrease successively in that sequence.

5. The optical element as claimed in claim 1,
wherein the polished layer contains a region that adjoins a surface of the polished layer that faces away from the substrate structure, wherein a proportion of OH molecules in that region is lower than in remaining regions of the polished layer.

6. The optical element as claimed in claim 1,
wherein the polished layer or the polished layer with the substrate structure is compacted in a region adjoining the surface of the polished layer that faces away from the substrate structure.

7. The optical element as claimed in claim 1,
wherein a reflection layer stack which is configured to reflect electromagnetic radiation incident on a surface of the reflection layer stack which is remote from the polished layer is disposed on a side remote from the substrate structure.

8. The optical element as claimed in claim 7, wherein the reflection layer stack comprises an interposed interlayer in the thickness direction of the substrate structure.

9. The optical element as claimed in claim 1,
wherein the substrate structure contains at least one cooling channel.

10. A lithography apparatus comprising:
an illumination system configured to transmit light from a light source to an object plane, and
a projection system configured to transmit the light from the object plane to an image plane,
wherein at least either the illumination system or the projection system comprises an optical element as claimed in claim 1.

11. A method of producing an optical element comprising:
a) providing a substrate structure containing a plurality of TiO₂—SiO₂-containing primary layers having mutually differing ratios of TiO₂ to SiO₂, where the primary layers follow one another and/or merge into one another in a thickness direction of the substrate structure, and where the substrate structure has a lateral face,
b) forming a concave figure in and/or on the lateral face of the substrate structure so as to intersect at least two of the primary layers, and
d) forming a polished layer having a thickness of no more than 500 μm-along the figure, wherein the polished layer contains TiO₂—SiO₂.

12. The method as claimed in claim 11,
wherein said providing in step a) includes providing of a primary layer containing Li₂O—Al₂O₃—SiO₂.

13. The method as claimed in claim 11,
wherein said providing in step a) after the providing of the plurality of TiO₂—SiO₂-containing primary layers includes: preforming the provided substrate structure by arranging the substrate structure on a negative mold with supply of heat.

14. The method as claimed in claim 11,
wherein said forming of the polished layer in step d) includes:
c) forming at least two part-layers of the figure,
wherein, in step a) and step d), a refractive index of the substrate structure or of at least one layer of the substrate structure adjacent to the figure and a respective refractive index of the part-layers of the polished layer are adjusted so as to increase or decrease successively in that sequence.

15. The method as claimed in claim 11,
wherein said forming of the polished layer in step d) includes:
e) forming the polished layer by thermal evaporation, wherein an object used for the evaporation is a TiO₂—SiO₂-containing source material, and/or
f) forming the polished layer by ion beam sputtering, wherein a target used for the sputtering is a TiO₂—SiO₂-containing source material.

16. The method as claimed in claim 11,
wherein said forming of the polished layer in step d) includes:
g) directly depositing the polished layer on the figure formed on the substrate structure by flame hydrolysis.

17. The method as claimed in claim 11,
wherein said forming of the polished layer in step d) includes:
h) soot deposition of a soot layer on the substrate structure by flame hydrolysis, and
k) forming the polished layer by sintering the soot layer.

18. The method as claimed in claim 11,
wherein said forming of the polished layer in step d) includes:
i) soot deposition of a soot,
j) shaping of a soot layer from the soot onto the substrate structure, and
k) forming the polished layer by sintering the soot layer.

19. The method as claimed in claim 11,
wherein said forming of the polished layer in step d) includes:
l) providing a sol-gel in which particles containing TiO₂—SiO₂ are formed, and
n) depositing particles of the sol-gel on the substrate structure.

20. The method as claimed in claim 11,
wherein said forming of the polished layer in step d) includes:
m) providing a sol-gel in which particles are formed, wherein the ratio of TiO₂ to SiO₂ in the particles is lower than in the polished layer, such that the particles contain less Ti than is contained in the polished layer,
n) depositing the particles of the sol-gel on the substrate structure, and
o) doping the deposited particles of the sol-gel with Ti.

21. The method as claimed in claim 11,
wherein said forming of the polished layer in step d) includes:
varying a ratio of TiO₂ to SiO₂.

22. The method as claimed in claim 21,
wherein said varying of the ratio of TiO₂ to SiO₂ varies especially along a local perpendicular to the figure.
